(19) United States
(12) Patent Application Publication
(10) Pub. No.: US 2009/0286105 A1
(43) Pub. Date: Nov. 19, 2009

(54) METHOD FOR PRODUCING A COATED ARTICLE BY SPUTTERING A CERAMIC TARGET

(75) Inventors: Daniel Severin, Maintal (DE); Matthias Wutting, Aachen (DE); Lothar Herlitze, Derenthal (DE); Hansjoerg Weis, Hoexter (DE)

Correspondence Address: SCULLY SCOTT MURPHY & PRESSER, PC, 400 GARDEN CITY PLAZA, SUITE 300, GARDEN CITY, NY, 11530, US

(73) Assignee: INTERPANE ENTWICKLUNGS-UND BERATUNGSGESELLSCHAFT MBH & CO. KG, Lauenfoerde (DE)

(21) Appl. No.: 12/306,568

(22) PCT Filed: Jun. 28, 2007
(86) PCT No.: PCT/EP2007/005750

§ 371 Date: Dec. 24, 2008

(30) Foreign Application Priority Data
Jun. 28, 2006 (DE) 10 2006 029 683.4
Sep. 28, 2006 (DE) 10 2006 046 126.6

(51) Int. Cl. B32B 18/00; C23C 14/34

(52) U.S. Cl. 428/702; 204/192.15

(57) ABSTRACT

The invention relates to a method for producing a coated article (1) by deposition of at least one metal oxide layer (3, 4) on a substrate (2). An oxygen-containing sputtering atmosphere is first produced in a coating chamber. A metal oxide layer is deposited on the substrate in that oxygen-containing atmosphere by sputtering a nitrogen-containing, ceramic target.

The invention relates to a method for producing a coated article by sputtering a ceramic target, and to an article so produced.

So-called cathode sputtering is conventionally used for the coating of articles, such as, for example, glass in the production of insulating glazing. Material is removed from a conductive material, which is referred to as the target, by ion bombardment. This material condenses on a surface of a substrate arranged in the vicinity and accordingly forms a thin layer on the substrate surface. In many applications it is required to dispose a metal oxide layer on the substrate surface. Such metal oxide layers are frequently used, for example, as antireflection layers in coatings for thermal insulation glazing.

For the application of the layers it is known from EP 0 795 623 A1 to sputter material from a metallic target in a reactive process atmosphere. In dependence on the reactive gas, which contains, for example, oxygen, nitrogen and carbon, a layer having the composition MeOₓN_{y}C_{z} forms on the substrate surface. The oxygen, nitrogen and carbon content in the layer on the substrate surface is thereby related to the proportions of the corresponding gases in the process gas. Because some process parameters are dependent in a sensitive manner on the composition of the gas, the gas flow of the process gas is regulated in order to control the process. To this end, rapid gas-flow control instruments or valves are so controlled that the desired layer properties are established. In a so-called hysteresis region it is necessary, in order to achieve a high deposition rate and at the same time the application of a transparent layer, to operate the target as the cathode in a region that is actually unstable.

It is also known, from WO 01/73151 A1, to adjust the oxygen flow, or the oxygen partial pressure, during the deposition operation in order to deposit a stoichiometric oxide on the substrate. However, because of the complex relationships, changes in individual coating parameters, such as, for example, the oxygen content in the process gas, lead to a mutual interaction with other parameters, so that it is extremely difficult to establish a stable working point. Because the process must take place in an unstable hysteresis region in order to achieve economically valuable deposition rates, rapid adjustment of the reactive gas can lead to the process being tilted out of that hysteresis region. The rate and the desired layer thickness as well as the interference colour of the coating are thereby changed. Reactive gas adjustment is critical in the case of a changing substrate coating in particular, because the reactive gas pressure can change rapidly as a result of the change in pump geometry when the substrate coating is changed, and sudden leaving of the established process window can accordingly occur.

It is additionally known, from EP 1 140 721 B1, to use oxygen-containing ceramic target materials for the application of metal oxide layers. As well as containing the metal which is the basis for the metal oxide to be deposited, such ceramic target materials already contain an oxygen component. Because of the oxygen component in the target material, the process gas can contain a smaller oxygen component. However, owing to the oxygen component in the target, the lower limit of the metal/oxygen mixture is already fixed by the target. This makes difficult, or prevents, the production of substoichiometric oxidic layers, which are advantageous in some applications.

Both when using oxygen-containing ceramic targets and when using metallic targets in an oxygen-containing sputtering atmosphere, it is disadvantageous that so-called bombardment of the substrate surface with high-energy oxygen atoms has an undesirable influence on the structure in the deposited metal oxide layer. While in the case of oxygen-containing ceramic targets oxygen coming directly from the target material is accelerated by the ion bombardment during the sputtering operation and accordingly strikes the substrate surface with high kinetic energy, purely metallic targets in an oxygen atmosphere tend to accumulate oxygen on their surface. The oxygen accumulated thereon is then in turn detached by the ion bombardment and strikes the substrate surface with high kinetic energy. This so-called bombardment leads in both cases to the undesirable occurrence of stresses in the deposited layer. Such stresses adversely affect both the chemical stability and the mechanical resistance. This particularly also affects layers that are applied subsequently, which are applied to such an antireflection layer.

The object of the invention is, therefore, to provide a method which provides simplified deposition of metal oxide layers on a substrate in order to produce coated articles, whereby a simplified procedure is achieved, and also to provide an article produced by this method.

The object is achieved by the method according to the invention having the features of claim 1.

According to the invention, a coated article is produced by depositing at least one metal oxide layer on a substrate. For the deposition of the substrate, an oxygen-containing sputtering atmosphere is produced. In that oxygen-containing sputtering atmosphere, the metal oxide layer is deposited by sputtering a nitrogen-containing ceramic target. The use of the ceramic, nitrogen-containing target not only prevents bombardment, because oxygen is not present in the target material directly, nor is oxygen able to accumulate on the surface of the target, but also at the same time reduces or completely prevents undesirable arcing during a sputtering process. It has been found, surprisingly, that the deposition of metal oxide layers on the substrate is possible when nitrogen-containing ceramic targets are used in an oxygen-containing atmosphere. During production of the metal oxide layer, oxygen contained in the process gas is incorporated into the layer. Within the scope of the invention the expression “metal oxide layer” is understood as meaning a predominantly oxidic layer based on the metal of the target. Predominantly oxidic layers are layers in which at least 50% of the oxygen that would be required to produce a stoichiometric metal oxide layer is present in the layer.

In the method according to the invention it is advantageous that the nitrogen contained in the target has the effect that the metal atoms on the target surface are for the most part already saturated by nitrogen bonds. Accordingly, only a small number of free metal atoms remain which could accept the oxygen mixed in the reactive gas. Consequently, the tendency to arcing decreases and the bombardment of the substrate surface is reduced. Accordingly, a relatively high oxygen flow can be established and the hysteresis behaviour is markedly moderated. Because a high oxygen flow can be established, a predominantly oxidic layer, which is optically transparent, is deposited on the substrate despite the nitrogen present in the target material.

Advantageous embodiments will become apparent from the dependent claims.

Accordingly, it is particularly advantageous to provide the metal oxide layer which is deposited according to the invention from the nitrogen-containing, ceramic target in the form of an antireflection layer, it being particularly advantageous to dispose such an antireflection layer beneath and/or above an infrared-reflecting functional layer. The expressions “beneath” and “above” here relate to the arrangement of the layer system on a substrate. The layer applied adjacent to the substrate is referred to as the lowermost layer. The subsequent layers are accordingly disposed “above” that lowermost layer.

It is particularly preferred to adjust the oxygen flow in the coating chamber in such a manner that an atomic ratio of oxygen to nitrogen of at least 5 is established in the metal oxide layer. It is thereby ensured that the metal oxide layer deposited on the substrate fulfils the required optical properties in particular in respect of its transparency in the visible range. Because of the moderated hysteresis characteristics it is possible in the method according to the invention to increase the oxygen flow until such a layer formation on the substrate is obtained. Because of the effects already mentioned above, there is no risk of the process becoming unstable.

The advantages are obtained in particular when nitrogen-containing ceramic targets of one of the elements Ti, Zn, Zr, Hf, Nb, Si, Al or a mixture thereof are used.

A particularly stable procedure can be established when the ceramic target has the composition MeNᵤ wherein u is at least 0.2 and not more than 1.2.

When using TiNᵤ targets in particular, it is advantageous for u to be from 0.2 to 1.2, there being deposited from the nitrogen-containing, ceramic titanium nitride target a metal oxide layer having the composition TiOₓN_{y} where x≧1.8 and y≦0.2. Particularly preferably, a layer having the composition x≧1.9 and y≦0.1 is deposited therefrom. The reaction with the oxygen in the process atmosphere can preferably be improved by increasing the oxygen flow in the atmosphere. Increased oxygen flows in the coating chamber thereby result in the deposition of oxidic metal layers having a higher oxygen content on the substrate.

With regard to the article that can be produced or has been produced by the method, the object is achieved by the features of claim 9.

Advantageous embodiments are shown in the drawings and are explained in detail in the following description. In the drawings:

FIG. 1 shows an example of a structure of a layer system produced by the method according to the invention;

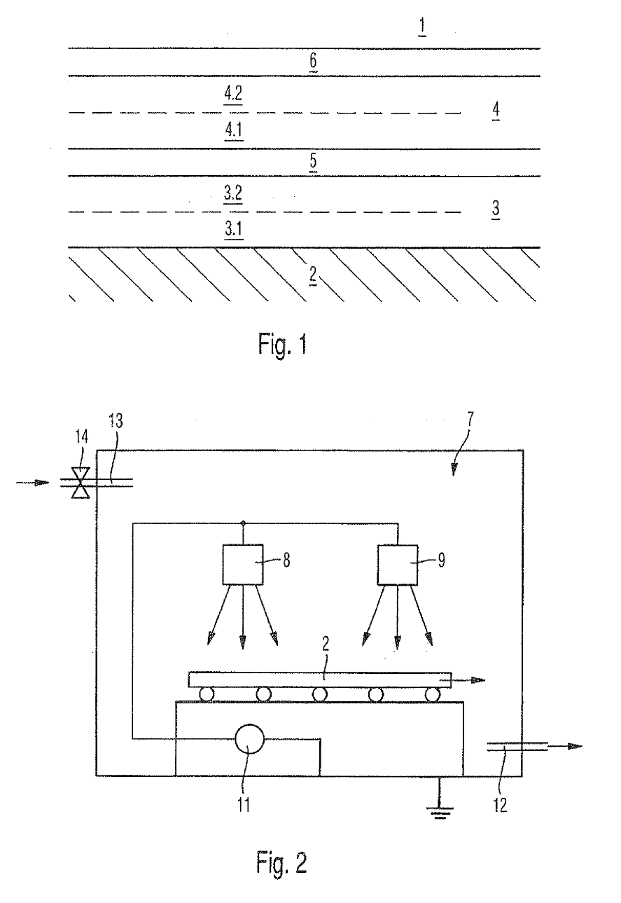

FIG. 2 shows a greatly simplified representation of a coating chamber for carrying out the method according to the invention;

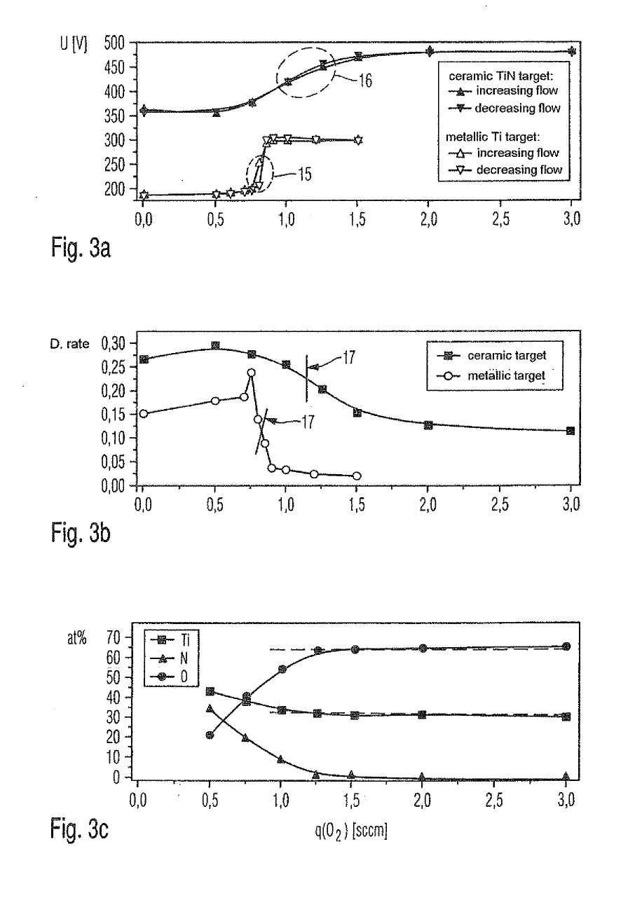

FIG. 3 shows a comparison of the process parameters for producing metal oxide layers between metallic targets and nitrogen-containing ceramic targets;

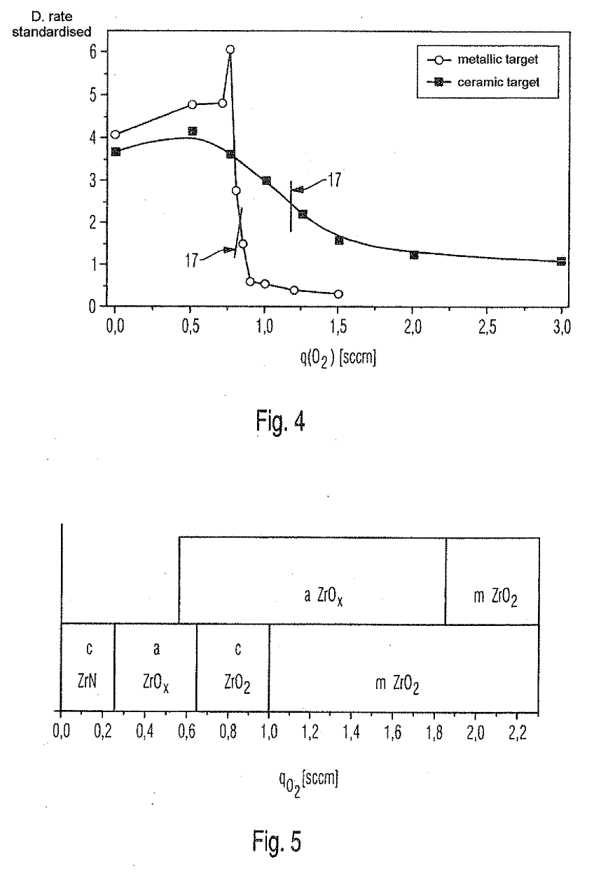

FIG. 4 shows a further comparison of the process parameters in the production of metal oxide layers by means of a metallic target and a nitrogen-containing ceramic target; and

FIG. 5 shows a diagrammatic representation to illustrate the influence of the target used on the resulting structures of a deposited zirconium oxide layer.

FIG. 1 shows, by way of example, a layer system as is used for thermal insulation glazing. The production of a coated article by the method according to the invention is not limited only to the production of such layer systems for thermal insulation glazing. On the contrary, other layer systems in which a metal oxide layer is used can also be produced by the method according to the invention. For example, antireflection layers or partial layers of a metal oxide are used for layer systems in spectacle lenses, window glazing, shop windows, solar cells, cover glasses for photovoltaic or solar thermal applications. Architectural glazing in thermal insulation or sun protection layers or highly reflective individual layers can also be produced by the method according to the invention.

FIG. 1 shows a layer system 1 which is particularly advantageously produced by the method according to the invention. The layer system 1 is disposed on a substrate 2. The substrate 2 can be a float glass, for example. Other substrate materials such as, for example, Plexiglas are also possible.

On the substrate 2 there is first disposed a first antireflection layer 3. The layer system l also has a second antireflection layer 4. The antireflection layers 3, 4 enclose an infrared-reflecting layer 5 in the manner of a sandwich. The infrared-reflecting layer 5 is a thin metallic layer, silver in particular being used as the infrared-reflecting layer. The infrared-reflecting layer 5 forms a functional layer in the layer system 1. This functional layer can have different characteristics depending on the field of use of the layer system employed, that is to say on the reflection in particular wavelength ranges. The exemplary embodiment shown relates to a so-called low-E coating as is used in thermal insulation glazing.

As is shown by the broken line in the first antireflection layer 3 and the second antireflection layer 4, the antireflection layers disposed above and beneath the infrared-reflecting layer 5 can comprise a plurality of partial layers 3.1 and 3.2 or 4.1 and 4.2, respectively. The layer structure of the antireflection layers is not limited to the two-layer arrangement that is shown. In particular, further layers are possible to produce selective layer systems. An adhesive layer can thereby be disposed on one side or on both sides of the silver layer in order to improve the stability.

In order to protect the stack of layers as a whole from the effects of weathering or during further processing of the coated article, a protective layer 6 is finally applied to the stack of layers and the layer system 1 is thereby completed.

In the exemplary embodiment shown, only a single infrared-reflecting layer 5 is provided. However, systems that comprise a plurality of infrared-reflecting layers, and in that case in particular thinner infrared-reflecting layers, are also possible. The infrared-reflecting layers are then preferably each separated from one another by at least one antireflection layer, a final antireflection layer finally being disposed on the outermost infrared-reflecting layer before the protective layer is deposited.

The method according to the invention is particularly preferably used to deposit the second partial layer 3.2 of the first antireflection layer 3 and the first partial layer 4.1 of the second antireflection layer 4 above and beneath, respectively, the infrared-reflecting layer 5. The high mechanical and chemical stability of the metal oxide layer deposited from the nitrogen-containing ceramic target can thereby be fully utilised. The metal oxide layer forms a diffusion barrier against alkali ions and oxygen.

The use of a nitrogen-containing ceramic target additionally reduces mechanical stresses by reducing the bombardment during the deposition process. The total stress in the layer system 1 as a whole is accordingly reduced, and the adhesion, abrasion resistance and wash resistance of the layer system 1 are thereby improved. In particular, zinc oxide layers deposited without stress are suitable, for example, as a growth layer for silver layers. The method according to the invention is therefore used in particular for the deposition of zinc oxide or zirconium oxide layers. These ensure that the grown silver layer has a lower surface resistivity.

FIG. 2 shows, in highly simplified form, a coating installation for carrying out the method according to the invention. A substrate material 2 is arranged in a coating chamber 7, which has been evacuated. In the exemplary embodiment shown, the substrate material 2 is guided past a first target 8 and a second target 9 so that uniform layer application is ensured. For controlling the sputtering operation, a voltage source 11 is connected to the two targets 8, 9 and to an installation housing that is at ground potential, so that a potential difference is produced between the targets 8, 9 and the substrate material 2. In the exemplary embodiment shown, the voltage source 11 is in the form of a direct-voltage source. However, it is also possible to carry out an alternating-voltage process. An alternating-voltage source is then arranged between the two targets 8, 9. In order to produce the necessary process atmosphere in the coating chamber 7, the gas located in the coating chamber 7 is extracted by a pump (not shown) via an evacuation connection 12. A specific process gas composition is produced in the coating chamber 7 via one or more gas inlets 13 under the control of a valve 14. The composition of the process gas is dependent on the composition of the target material of the targets 8 and 9 and on the desired composition in the metal oxide layer on the substrate 2.

FIG. 3 shows the deposition process for a metal oxide layer by the method according to the invention in comparison with a sputtering process of a metal target in an oxygen-containing atmosphere to produce a metal oxide layer. FIG. 3a shows the hysteresis behaviour both for the use of a metallic target and for the use of a nitrogen-containing ceramic target. It will be seen that, as the oxygen flow in the coating chamber 7 increases, an increase in the power used is required in both cases. The rising edge and the falling edge are displaced relative to one another. The expression hysteresis is used in this context. It can clearly be seen that the hysteresis behaviour in the case of the ceramic TiN target is markedly less pronounced than in the case of the use of a metallic titanium target. This is particularly important because, precisely in that range, which is indicated in FIG. 3a by 15 for the metallic Ti target, a transparent layer can still be produced at economically valuable deposition rates.

When the ceramic TiN target is used, on the other hand, the hysteresis behaviour in region 16, in which the transition from transparent to absorbing layers takes place, is substantially less pronounced. In addition, the progression of the curves for the ceramic TiN target is considerably flatter, so that the effect of changes in the process parameters is less pronounced.

FIG. 3b shows the deposition rate for both a metallic target and a ceramic, nitrogen-containing target. The boundary line 17 indicates approximately the oxygen flow limit in the coating chamber 7 for the application of absorbing layers. If the oxygen flow is increased beyond that limit, then transparent layers are deposited, as are required for the production of an antireflection layer, but the deposition rate falls at the same time. FIG. 3b also clearly shows that the transition between absorbing and transparent layers lies in a steep, falling region when a metallic target is used.

The progression of the deposition rate when a nitrogen-containing, ceramic target is used, on the other hand, is higher overall and, in particular in the transition region from absorbing to optically transparent layers, is substantially flatter. Together with the improved hysteresis behaviour, the result is that it is substantially simpler to establish a stable working point for a nitrogen-containing, ceramic target than for a metallic target. In particular, it is possible to reduce the oxygen content to a relatively large extent, which leads to an increase in the deposition rate.

At the same time, the process remains stable because, owing to the moderate relationship with the oxygen flow, a sudden tilting out of the process window during the process is not to be expected, provided that only relatively small variations in the oxygen flow occur. On the other hand, when a metallic titanium target is used, only a small change in the oxygen flow can lead to the process being tilted out of the process window because the sudden rise in the deposition rate is immediately accompanied by the transition to absorbing layers.

FIG. 3c shows the composition of the resulting metal oxide layer on the substrate 2. The expression predominantly oxidic layer refers to a metal oxide layer in which the atomic ratio of oxygen to nitrogen is greater than 3, in particular greater than 5. An atomic ratio of oxygen to nitrogen of at least 5 ensures that optically transparent layers are deposited on the substrate, which layers can be used in optical layer systems 1 as antireflection layers 3, 4.

It can readily be seen that, as the oxygen flow in the coating chamber 7 increases, the incorporation of nitrogen in the deposited layer decreases asymptotically in the direction 0 despite the presence of nitrogen in the target, while the oxygen component increases considerably. The presence of nitrogen in the target therefore does not impair the optical layer properties but assists the sputtering process by preventing arcing and also by reducing bombardment with rapid oxygen atoms considerably.

It will be seen in FIG. 3 that the rate, standardised to the power used, in the case of sputtering of nitridic targets, as compared with the sputtering of metallic targets, is approximately in the ratio of 22 to 15, if there are compared with one another the first transparently deposited layers, which in FIGS. 3a, 3b the first samples lying in each case to the right of the boundary line 17. In the case of metallic targets, it is difficult to establish a stable working point because of the steep rise in the negative target voltage as the oxygen component in the process atmosphere increases and an offset, likewise steep fall in the negative target voltage as the oxygen content falls. In order to achieve expedient deposition rates, however, it is necessary to establish a working point in precisely that region.

A comparison of FIGS. 3a, b and c shows that higher oxygen components in the sputtering gas are possible for ceramic, nitridic targets, the deposition rate being markedly less negatively affected than in the case of a metallic target. High deposition rates result therefrom, it being possible at the same time to ensure that the grown layer is transparent. FIG. 3c shows that the deposited layer is applied predominantly as an oxidic layer.

FIG. 4 again shows a standardised deposition rate both for a metallic target and for a nitridic ceramic target, The moderate progression on transition from absorbing to transparent layers, which is again indicated by the separating lines 17, can clearly be seen therein. Accordingly, the establishment of a higher oxygen content in the process gas has the effect that the deposition rate is only slightly behind, but at the same time it is possible to ensure that a transparent layer is present. Conversely, it is possible by reducing the oxygen component to effect an increase in the deposition rate, it nevertheless being possible to establish a stable process because the reaction of the deposition rate, like the transition to absorbing layers, is more readily controllable owing to the moderate relationship.

In addition to the more advantageous process-related properties in the case of the sputtering of nitrogen-containing, ceramic targets, the layer properties are also positively affected. For example, for TiOₓ an increase in the refractive index from n≦2.4 to n≧2.5 at a wavelength of 550 nm is achieved. In addition to an advantageous increase in the refractive index, the bombardment of the deposited layer by high-energy oxygen ions is also greatly reduced. This reduction in bombardment at the same time reduces mechanical stresses. The use of a nitrogen-containing target therefore results in a layer of low mechanical stress, leading to improved adhesion and accordingly a more resistant layer structure. At the same time, the layer structure can advantageously be influenced and, for example, cubic zirconium oxide can also be deposited.

FIG. 5 shows a comparison between the achievable layer structures when using a metallic target (top half) and a nitrogen-containing, ceramic target (bottom half). While amorphous zirconium oxide (ZrOₓ) is deposited as a layer on the substrate over a large range in respect of the oxygen component in the process gas when a metallic target is used and, as the oxygen component increasesr zirconium oxide in monoclinic phase (region m) is deposited, it is possible by means of the method according to the invention also to deposit a cubic phase of zirconium oxide. Compared with the use of metallic targets, the interval for the oxygen flow in which an amorphous zirconium oxide phase is deposited is reduced. Additional intervals in which the zirconium oxide is deposited in cubic form are thereby formed. Such an influence on the crystal structure can advantageously be used, for example, to improve the adhesion of subsequent layers. To this end, each deposited phase is so adjusted, by adjusting the oxygen flow when using a nitridic target, that there is established in the deposited layer a phase to which the layer that is subsequently to be applied adheres particularly well.

The use of nitridic targets additionally has the advantage that additional doping is not absolutely necessary in order to achieve the conductivity of the target. The side-group nitrides are in most cases already conductive, so that it is not necessary to add further elements, which are also incorporated in an undesirable manner in the layer. For carrying out the method according to the invention, nitrogen-containing, ceramic targets having the composition MeNᵤ have proved to be advantageous, in which u is at least 0.2 and not more than 1.2. In particular for the production of predominantly oxidic TiOₓN_{y}, TiNᵤ targets wherein u≧0.2 and ≦1.2 have proved to be advantageous, the deposited layer having a composition TiOₓN_{y} wherein x≧1.8 and y≦0.2. It is particularly preferred to adjust the oxygen flow in the coating chamber 7 in such a manner that x is at least 1.9 and y is not more than 0.1. As has already been indicated in the explanation of FIG. 3c, a corresponding increase in the oxygen flow is sufficient therefor because, at the same time as the oxygen content increases, the oxygen component in the deposited layer increases, while the proportion of incorporated nitrogen is reduced.

Further elements with which metal oxide layers can be deposited from a nitridic, ceramic target by sputtering in an oxygen-containing atmosphere are, for example, in addition to Ti, Zn, Zr already mentioned, Hf, Nb, Si, Al or mixtures of the elements.

The invention is not limited to the exemplary embodiments described. On the contrary, in addition to the ceramic, nitrogen-containing targets of titanium, zirconium and zinc which have already been mentioned explicitly, the use of other ceramic, nitrogen-containing targets is also possible.

1. Method for producing a coated article by deposition of at least one metal oxide layer on a substrate, comprising the following method steps:
production of an oxygen-containing sputtering atmosphere,
deposition of the metal oxide layer by sputtering a nitrogen-containing ceramic target in the oxygen-containing sputtering atmosphere.

2. Method according to claim 1,
wherein
at least one further functional layer is deposited on the substrate, wherein there is deposited beneath and/or above the further functional layer at least one antireflection layer which comprises at least one partial layer which is deposited as a metal oxide layer from the nitrogen-containing, ceramic target.

3. Method according to claim 2,
wherein
an infrared-reflecting layer is deposited as the functional layer.

4. Method according to claim 1,
wherein
the atomic ratio of oxygen to nitrogen in the metal oxide layer is at least 5.

5. Method according to claim 1,
wherein
the nitrogen-containing ceramic target comprises one of the elements Ti, Zn, Zr, Hf, Nb, Si, Al or a mixture thereof.

6. Method according to claim 5,
wherein
the nitrogen-containing ceramic target has the composition MeNᵤ wherein u is at least 0.2 and not more than 1.2.

7. Method according to claim 1,
wherein
a metal oxide layer having the composition TiOₓN_{y} wherein x>=1.8 and y<=0.2 is deposited by sputtering a TiNᵤ target wherein 0.2<=u<=1.2.

8. Method according to claim 7,
wherein
a metal oxide layer having the composition TiOₓN_{y} wherein x>=1.9 and y<=0.1 is deposited by sputtering a TiNᵤ target wherein 0.2<=u<=1.2.

9. Coated article which can be produced or has been produced in accordance with the method of claim 1.
